(19) United States
(12) Patent Application Publication
(10) Pub. No.: US 2016/0269023 A1
(43) Pub. Date: Sep. 15, 2016

(54) SEMICONDUCTOR SWITCH AND SWITCHING SYSTEM

(71) Applicant: Kabushiki Kaisha Toshiba, Tokyo (JP)

(72) Inventor: Toshiki Seshita, Kawasaki Kanagawa (JP)

(21) Appl. No.: 14/837,835

(22) Filed: Aug. 27, 2015

(30) Foreign Application Priority Data
Mar. 12, 2015 (JP) 2015-049600

(51) Int. Cl. H03K 17/687; H03M 9/00

(52) U.S. Cl. CPC H03K 17/6871; H03K 17/687; H03M 9/00

(57) ABSTRACT

According to an embodiment, a semiconductor switch includes a serial interface circuit, a drive circuit, a switching circuit and a multi-value conversion circuit. The serial interface circuit is configured to convert serial data into parallel data. The drive circuit is configured to generate a control signal having two values including a first positive potential and a negative potential, based on the parallel data. The switching circuit is configured to switch a plurality of signal paths based on the control signal. The multi-value conversion circuit is configured to convert control data included in the parallel data into a multi-value parallel signal. The multi-value parallel signal includes at least four values including the first positive potential and the negative potential.

### CROSS REFERENCE TO RELATED APPLICATION

This application is based upon and claims the benefit of priority from the prior Japanese Patent Application No.

2015-049600 filed on Mar. 12, 2015 in Japan, the entire contents of which are incorporated herein by reference.

### FIELD

Embodiments described herein relate generally to a semiconductor switch and a switching system.

### BACKGROUND

A high frequency circuit in a portable terminal, such as a portable phone, includes a transmission circuit and a receiving circuit, with each circuit being selectively connected to a common antenna via a high frequency switching circuit. In such a high frequency switching circuit of the past, a switching element that uses a high electron mobility transistor (HEMT) made of a compound semiconductor has been used. However, due to recent needs for decreasing the cost and size of a semiconductor device, the HEMT has been replaced by a metal oxide semiconductor field effect transistor (MOSFET) that is formed on a silicon substrate.

The MOSFET, however, when formed on an ordinary silicon substrate, has a problem, such as a large parasitic capacitance between a source electrode or a drain electrode and the silicon substrate, and a large power loss of the high frequency signal due to the silicon substrate being made of a semiconductor. Therefore, a technique of forming a high frequency switching circuit on a silicon on insulator (SOI) substrate has been proposed.

Recently, multi-mode and multi-band portable phones or the like have further been developed and more than 10 ports are required therein for a high frequency switch. As the number of ports is increased, a larger number of bits of a signal are required for controlling connection states of the switch. For example, in a single-pole 10-throw (SP10T) switch, which switches connection states between an antenna terminal and ten RF terminals, at least ten connection states have to be provided, and a necessary number of bits of the control signal are 4 bits. To input a 4-bit control signal in parallel, four terminals should be needed. This input method is usually referred to as a general purpose input/output (GPIO) method.

In contrast, there is another input method in which a serial data signal is input in synchronism with a clock signal. This input system will hereinafter be referred to as a serial input method. This serial input method has a merit in that one input terminal is sufficient regardless of the increase of the ports. Because of this, the need for the serial input method has been increased lately, although the GPIO method has been the main stream of the high frequency switching method.

Another merit of the serial input method is that a plurality of integrated circuits (ICs) other than the high frequency switch can be controlled with the same serial data line. To connect the plurality of ICs to one serial data line, each IC requires an identification (ID) to distinguish each IC. In addition to the ID, registers are provided to store various types of control information, and data to be stored in such registers are communicated bidirectionally. As a result, the size of a serial interface circuit becomes relatively large.

When a plurality of high frequency semiconductor switches are provided in one portable terminal, and the serial interface circuit is provided for each switch, the size of the high frequency semiconductor switch becomes large.

### BRIEF DESCRIPTION OF THE DRAWINGS

FIG. 1 is a block diagram of a high frequency module according to a first embodiment.

FIG. 2 is a block diagram of a first semiconductor switch of FIG. 1.

FIG. 3 is a block diagram of a second semiconductor switch of FIG. 1.

FIG. 4 is a circuit diagram of a first switching circuit of FIG. 2.

FIG. 5A is a circuit diagram illustrating a part of a multi-value conversion circuit of FIG. 2.

FIG. 5B is a truth table corresponding to the circuit of FIG. 5A.

FIG. 6 is a circuit diagram illustrating a tri-state level shifter.

FIG. 7 is a block diagram of a high frequency module according to a second embodiment.

FIG. 8 is a block diagram of a first semiconductor switch of FIG. 7.

FIG. 9 is a waveform diagram of a clock signal CK2 and second serial data Data2.

FIG. 10 is a block diagram of a second semiconductor switch of FIG. 7.

FIG. 11 is a block diagram illustrating a serial-parallel conversion circuit of FIG. 10.

FIG. 12 is a block diagram of a high frequency module according to a third embodiment.

FIG. 13 is a waveform diagram of a clock signal CK3 and second serial data Data3.

FIG. 14 is a block diagram of a second semiconductor switch of FIG. 12.

FIG. 15 is a block diagram of a high frequency module according to a fourth embodiment.

FIG. 16 is a block diagram of a signal extraction circuit.

FIG. 17 is a waveform diagram illustrating second serial data Sig1, a reset signal Reset, a clock signal CK4, and third serial data Data4.

FIG. 18 is a block diagram of a high frequency module according to a fifth embodiment.

FIG. 19 is a block diagram of a high frequency module of a comparative example.

### DETAILED DESCRIPTION

According to an embodiment, a semiconductor switch includes a serial interface circuit, a drive circuit, a switching circuit and a multi-value conversion circuit. The serial interface circuit is configured to convert serial data into parallel data. The drive circuit is configured to generate a control signal having two values including a first positive potential and a negative potential, based on the parallel data. The switching circuit is configured to switch a plurality of signal paths based on the control signal. The multi-value conversion circuit is configured to convert control data included in the parallel data into a multi-value parallel signal. The multi-value parallel signal includes at least four values including the first positive potential and the negative potential.

Embodiments will now be explained with reference to the accompanying drawings.

### First Embodiment

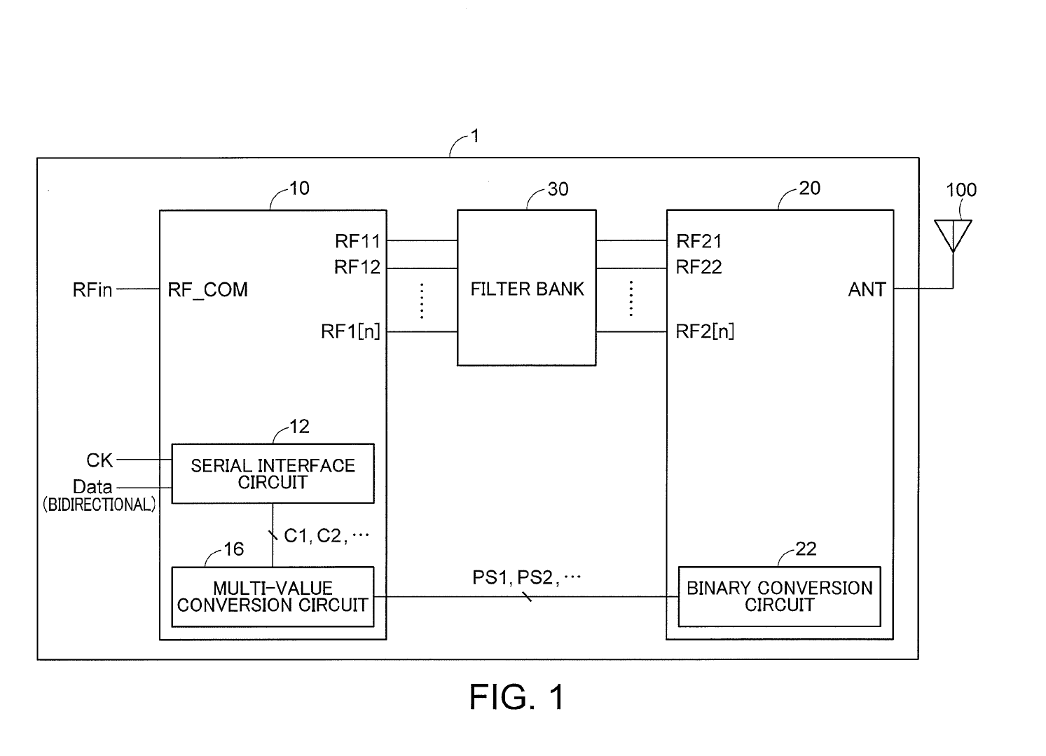

FIG. 1 is a block diagram of a high frequency module (switching system) 1 according to a first embodiment. The high frequency module 1 is provided in a wireless communication device, such as a portable phone. As illustrated in FIG. 1, the high frequency module 1 includes a first semiconductor switch 10, a second semiconductor switch 20, and a filter bank 30.

A high frequency signal RFin, which is supplied from a power amplifier (not illustrated), passes through the first semiconductor switch 10, the filter bank 30, and the second semiconductor switch 20 in this order, and is output to an antenna 100.

The first semiconductor switch 10 selects one high frequency signal terminal among a plurality of high frequency signal terminals (first signal nodes) RF11 to RF1[n] (n is an integer equal to or larger than 2) based on an input clock signal CK and serial data Data, and connects an RF common terminal (first common node) RF_COM to the selected high frequency signal terminal. The second semiconductor switch 20 selects one high frequency signal terminal among a plurality of high frequency signal terminals (second signal nodes) RF21 to RF2[n], based on multi-value parallel signals PS1, PS2, and so on, which are supplied from the first semiconductor switch 10, and connects the selected high frequency signal terminal to an antenna terminal (second common node) ANT. The filter bank 30 includes n filters (not illustrated), each filter having a different frequency characteristic. Each filter in the filter bank 30 is connected between a corresponding high frequency signal terminal among the high frequency signal terminals RF11 to RF1[n] and a corresponding high frequency signal terminal among the high frequency signal terminals RF21 to RF2[n]. Accordingly, the high frequency signal RFin, which has been supplied to the RF common terminal RF_COM, passes through an appropriate filter in the filter bank 30 and is transmitted from an antenna 100 connected to the antenna terminal ANT. The clock signal CK and the serial data Data are also supplied to the power amplifier or other semiconductor switches (not illustrated) in the wireless communication device.

The first semiconductor switch 10 can be provided as a one-chip switch, but may also be implemented by more than one chip, or some constituent components of the switch may be formed by discrete parts. In the present embodiment, the first semiconductor switch 10 is entirely formed on the SOI substrate. Since the SOI substrate has high resistance, a signal loss due to the leakage of the high frequency signal to the substrate side can be suppressed. The second semiconductor switch 20 can also be formed as in the first semiconductor switch 10.

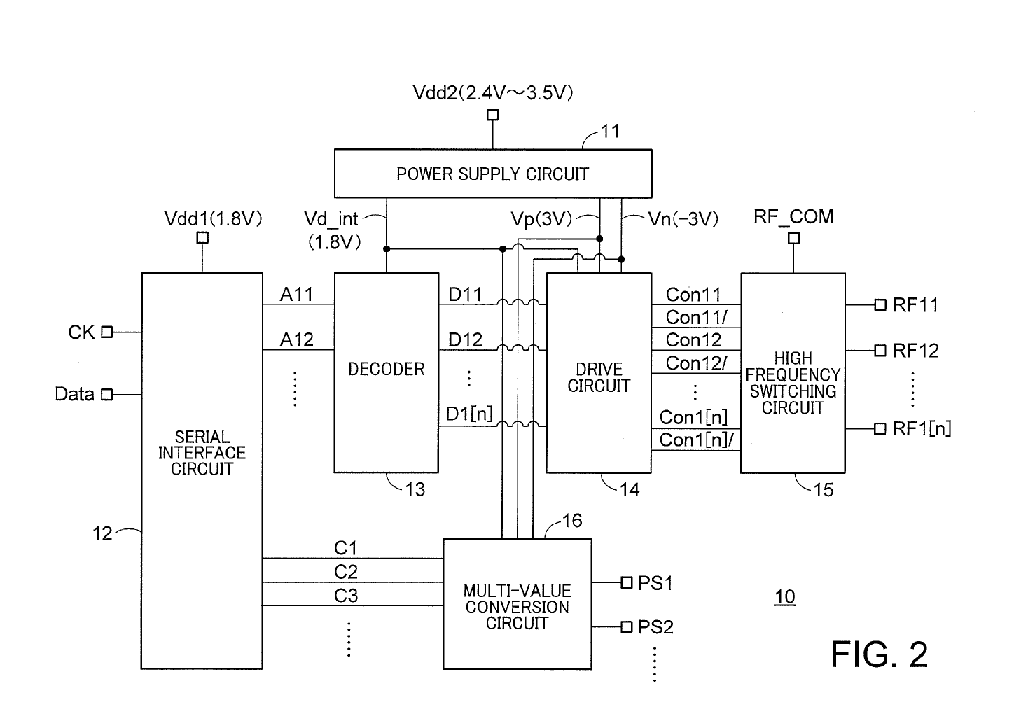

FIG. 2 is a block diagram of the first semiconductor switch 10 of FIG. 1. As illustrated in FIG. 2, the first semiconductor switch 10 includes a power supply circuit 11, a serial interface circuit 12, a decoder 13, a drive circuit 14, a high frequency switching circuit (hereinafter referred to as a first switching circuit) 15, and a multi-value conversion circuit 16.

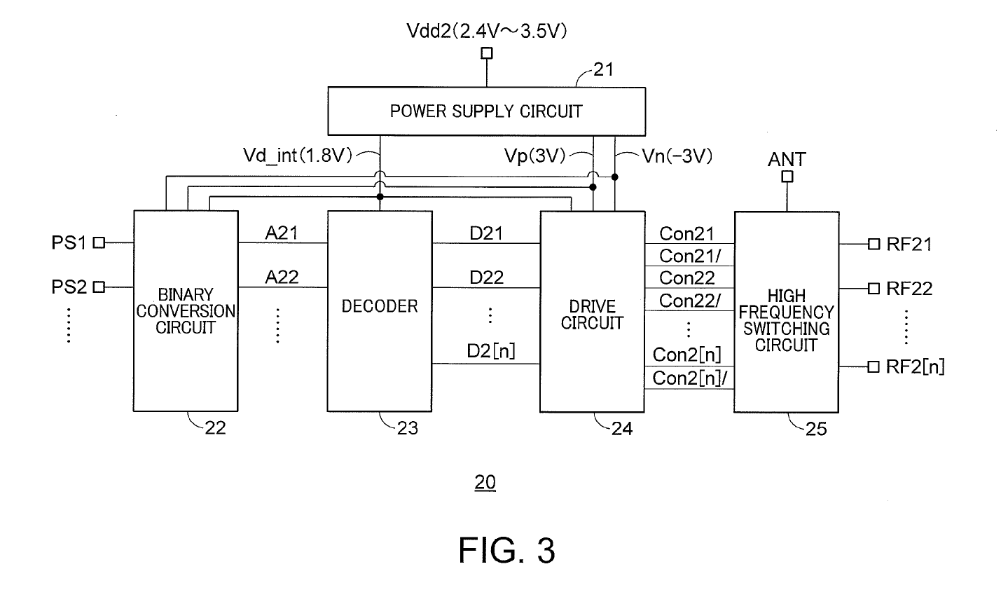

FIG. 3 is a block diagram of the second semiconductor switch 20 of FIG. 1. As illustrated in FIG. 3, the second semiconductor switch 20 includes a power supply circuit 21, a binary conversion circuit 22, a decoder 23, a drive circuit 24, and a high frequency switching circuit (hereinafter referred to as a second switching circuit) 25.

First, the first semiconductor switch 10 will be described.

The power supply circuit 11 generates, based on an external power supply potential Vdd2, a first positive potential Vp, a second positive potential Vd_int, and a negative potential Vn. Although not illustrated, the power supply circuit 11 includes a first charge pump that generates the first positive potential Vp, a second charge pump that generates the negative potential Vn, and a step-down circuit that generates the second positive potential Vd_int. Both the first positive potential Vp and the negative potential Vn are supplied to the drive circuit 14 and the multi-value conversion circuit 16. The second positive potential Vd_int is supplied to the decoder 13, the drive circuit 14, and the multi-value conversion circuit 16. For example, the external power supply potential Vdd2 may be 2.4 V to 3.5 V, the first positive potential Vp may be 3 V, the second positive potential Vd_int may be 1.8 V, and the negative potential Vn may be −3 V.

An external power supply potential Vdd1 (e.g., 1.8 V) is supplied to the serial interface circuit 12 which is synchronized with the clock signal CK to convert the serial data Data into parallel data, and stores the obtained parallel data in a register. The serial interface circuit 12 may include, for example, about ten 8-bit registers to which the parallel data is written.

The serial interface circuit 12 supplies, among the parallel data stored therein, control data A11, A12, and so on for controlling the first switching circuit 15 of the first semiconductor switch 10 to the decoder 13. The serial interface circuit 12 also supplies control data C1, C2, and so on for controlling the second switching circuit 25 of the second semiconductor switch 20 to the multi-value conversion circuit 16.

The parallel data stored in the serial interface circuit 12 includes various control information in addition to the control data for the first and second switching circuits 15, 25. The serial interface circuit 12 is capable of performing bidirectional communication in which the data, such as the various control information stored in the internal register, is read, and the read data may be output as the serial data Data in synchronism with the clock signal CK.

The decoder 13 decodes the control data A11, A12, and so on, and supplies the obtained decode signals D11 to D1[n] to the drive circuit 14.

The clock signal CK, the serial data Data, the control data A11, A12, and so on, the control data C1, C2, and so on, and the decode signals D11 to D1[n] have two values including the second positive potential Vd_int and reference potential. The reference potential is, for example, 0 V.

The drive circuit 14 converts the level of the decode signal D11 to D1[n], while performing single phase differential conversion, and supplies obtained control signals Con11 to Con1[n], Con11/ to Con1[n]/ to the first switching circuit 15. That is, the drive circuit 14 generates the control signals Con11 to Con1[n], Con11/ to Con1[n]/, which have two values of the first positive potential Vp and the negative potential Vn based on the parallel data stored in the serial interface circuit 12. The control signal Con11/ herein represents a logically inversed signal of the control signal Conn, and the symbol “/” represents similarly in other signals.

The first switching circuit 15 is a single-pole n-throw (SPnT) switch that switches a plurality of high frequency signal paths based on the control signals Con11 to Con1[n], Con11/ to Con1[n]/. Specifically, the first switching circuit 15 selects one high frequency signal terminal from the plurality of high frequency signal terminals RF11 to RF1[n], and connects it to the RF common terminal RF_COM. A high frequency signal RFin is supplied to the RF common terminal RF_COM, and the high frequency signal terminals RF11 to RF1[n] are connected to the filter bank 30.

The multi-value conversion circuit 16 converts the control data C1, C2, and so on for controlling the second semiconductor switch 20 into multi-value parallel signals PS1, PS2, and so on, which have four values including the first positive potential Vp, the second positive potential Vd_int, the negative potential Vn, and the reference potential. The multi-value conversion circuit 16 supplies the multi-value parallel signals PS1, PS2, and so on to the second semiconductor switch 20.

For example, if the second switching circuit 25 of the second semiconductor switch 20 is the SP12T switch (n=12), 4-bit control data C1 to C4 are necessary. In this case, the control data C1 to C4 can be converted into the multi-value parallel signals PS1, PS2 in this embodiment, in order to represent 4 bits by these two multi-value parallel signals PS1, PS2.

Next, the second semiconductor switch 20 will be described. The power supply circuit 21, the decoder 23, the drive circuit 24, and the second switching circuit 25 of the second semiconductor switch 20 have the functions similar to those of the power supply circuit 11, the decoder 13, the drive circuit 14, and the first switching circuit 15 of the first semiconductor switch 10. The description below will focus on what differs from the first semiconductor switch 10.

The binary conversion circuit 22 converts the multi-value parallel signals PS1, PS2, and so on, each having four values, into the binary parallel data A21, A22, and so on based on the first positive potential Vp, the second positive potential Vd_int, the negative potential Vn, and the reference potential. That is, one multi-value signal PS1 is, for example, converted into two parallel data A21, A22.

The decoder 23 decodes the parallel data A21, A22, and so on and supplies the obtained decode signal D21 to D2[n] to the drive circuit 24.

The parallel data A21, A22, and so on, and the decode signals D21 to D2[n] have two values including the second positive potential Vdd_int and the reference potential.

The drive circuit 24 converts the level of the decode signals D21 to D2[n], while performing single phase differential conversion, and supplies the obtained control signals Con21 to Con2[n], Con21/ to Con2[n]/ to the second switching circuit 25. That is, the drive circuit 24 generates the control signals Con21 to Con2[n], Con21/ to Con2[n]/, which have two values including the first positive potential Vp and the negative potential Vn, based on the parallel data A21, A22, and so on.

The second switching circuit 25 switches the plurality of high frequency signal paths based on the control signals Con 21 to Con 2[n], Con21/ to Con2[n]/. Specifically, the second switching circuit 25 selects one high frequency signal terminal among the plurality of high frequency signal terminals RF21 to RF2[n], and connects it to the antenna terminal ANT. The high frequency signal terminals RF21 to RF2[n] are connected to the filter bank 30, and the antenna terminal ANT is connected to the antenna 100.

A high frequency module 1X of a comparative example will be described.

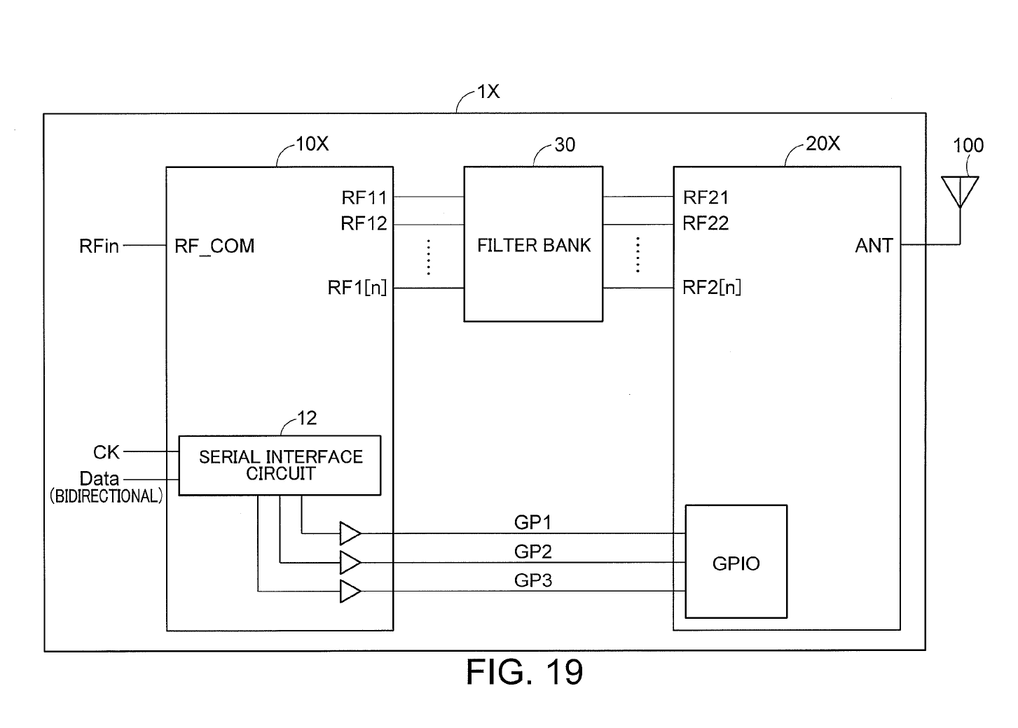

FIG. 19 is a block diagram of the high frequency module 1X of the comparative example. The serial interface circuit 12 of a first semiconductor switch 10X outputs GPIO control signals GP1 to GP3 that are binary parallel signals. A second semiconductor switch 20X switches a plurality of high frequency signal paths based on the GPIO control signals GP1 to GP3. Such a structure is advantageous in that, since the second semiconductor switch 20X does not include the serial interface circuit 12, the size of the second semiconductor switch 20X can be decreased when the bit number of the GPIO control signals GP1 to GP3 is small. As, however, the bit number of the GPIO control signals GP1 to GP3 is increased, the number of the output terminals of the first semiconductor switch 10X and the input terminals of the second semiconductor switch 20X are also increased correspondingly. As a result of this, the sizes of the first and second semiconductor switches 10X, 20X are increased.

For example, when the switching circuit of the second semiconductor switch 20X is the SP12T switch, the first semiconductor switch 10X and the second semiconductor switch 20X are connected by four signal lines to supply 4-bit GPIO control signals GP1 to GP4.

In contrast, two signal lines are sufficient in the present embodiment in order to supply the multi-value parallel signals PS1, PS2 based on the 4-bit control data C1 to C4. Accordingly, it is possible to decrease, compared to the comparative example, the number of the input terminals, the output terminals, input pads, output pads, as well as the number of electrostatic discharge (ESD) protection elements that are connected to the above components. Accordingly, the chip size of the first and second semiconductor switches 10, 20 can be decreased and made smaller than those of the comparative example.

The structure of the first switching circuit 15 is not specifically limited, and an example structure thereof will be described below. The second switching circuit 25 has a similar structure.

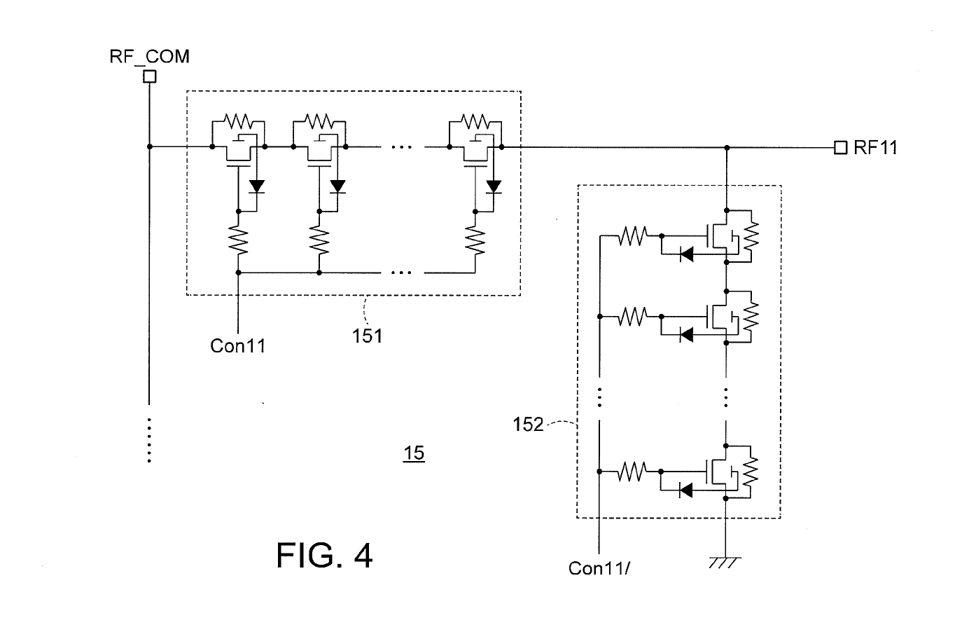

FIG. 4 is a circuit diagram of the first switching circuit 15 of FIG. 2. The first switching circuit 15 includes a unit through switch 151 connected between the common RF terminal RF_COM and each of the plurality of high frequency terminals RF11 to RF1[n], and a unit shunt switch 152 connected between each of the plurality of high frequency terminals RF11 to RF1[n] and the reference potential. In FIG. 4, the structure regarding the high frequency terminal RF11 alone is illustrated.

The unit through switch 151 includes a plurality of MOSFETs, which have been connected serially in multiple stages, PN junction diodes, each connected between the body and a gate of each MOSFET, first resistance connected to the gate of each MOSFET, and second resistance connected between the source and the drain of each MOSFET.

The control signal Con11 is supplied to each gate of the MOSFETs of the unit through switch 151 via the first resistance.

The structure of the unit shunt switch 152 is similar to that of the unit through switch 151, and the control signal Con11/ is supplied to each gate of the MOSFETs of the unit shunt switch 152 via the first resistance.

The MOSFET used in the first switching circuit 15 is N-type, and its threshold voltage Vth is, for example, about 0 V. As mentioned above, a high level of the control signals Con11 to Con1[n], Con11/ to Con1[n]/ is the first positive potential Vp (3 V), and a low level thereof is the negative potential Vn (−3 V).

The structure of the multi-value conversion circuit 16 is not specifically limited, and an example structure will be described below.

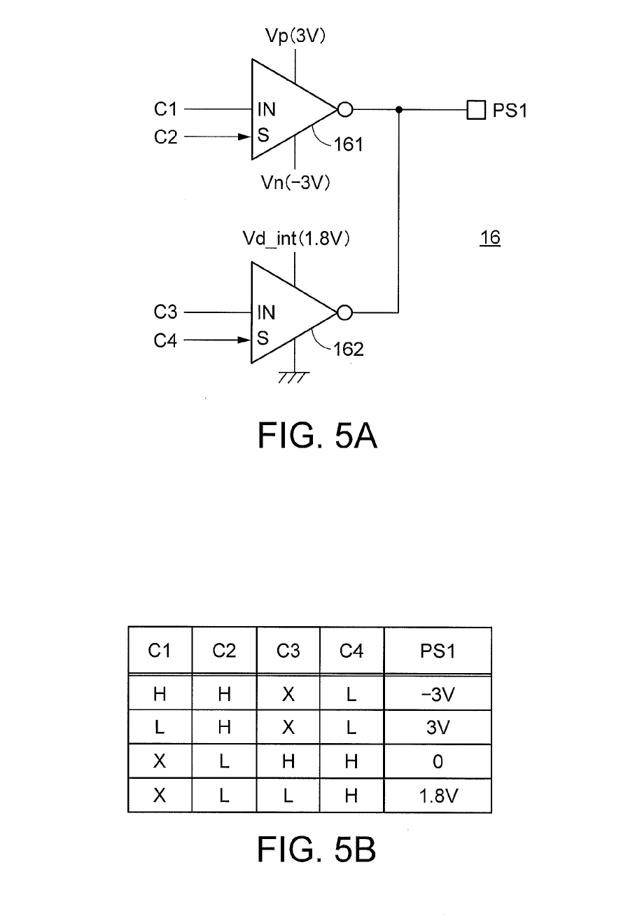

FIG. 5A is a circuit diagram illustrating a part of the multi-value conversion circuit 16 of FIG. 2. FIG. 5B is a truth table corresponding to the circuit of FIG. 5A.

In FIG. 5A, only a part of the circuit from which the multi-value parallel signal PS1 is output is illustrated, but a circuit that outputs a multi-value signal PS2 or the like may be similarly structured. The multi-value conversion circuit 16 includes a tri-state level shifter 161 and a tri-state inverter 162.

In the tri-state level shifter 161 and the tri-state inverter 162, when a selector terminal S is at the high level, the signal at the input terminal IN is inverted and output therefrom. When the selector terminal S is at the low level, the output terminal is brought to a high impedance state.

As illustrated in FIG. 5B, therefore, when the control data C1, C2 are at the high level and the control data C4 is at the low level, the multi-value parallel signal PS1 is at the negative potential Vn (−3 V) regardless of the control data C3. When the control data C2 is at the high level, and the control data C1, C4 are at the low level, the multi-value parallel signal PS1 is at the first positive potential Vp (+3 V), regardless of the control data C3. When the control data C3, C4 are at the high level, and the control data C2 is at the low level, the multi-value parallel signal PS1 is at the reference potential (0 V), regardless of the control data C1. When the control data C4 is at the high level and the control data C2, C3 are at the low level, the multi-value parallel signal PS1 is at the second positive potential Vd_int (+1.8 V), regardless of the control data C1.

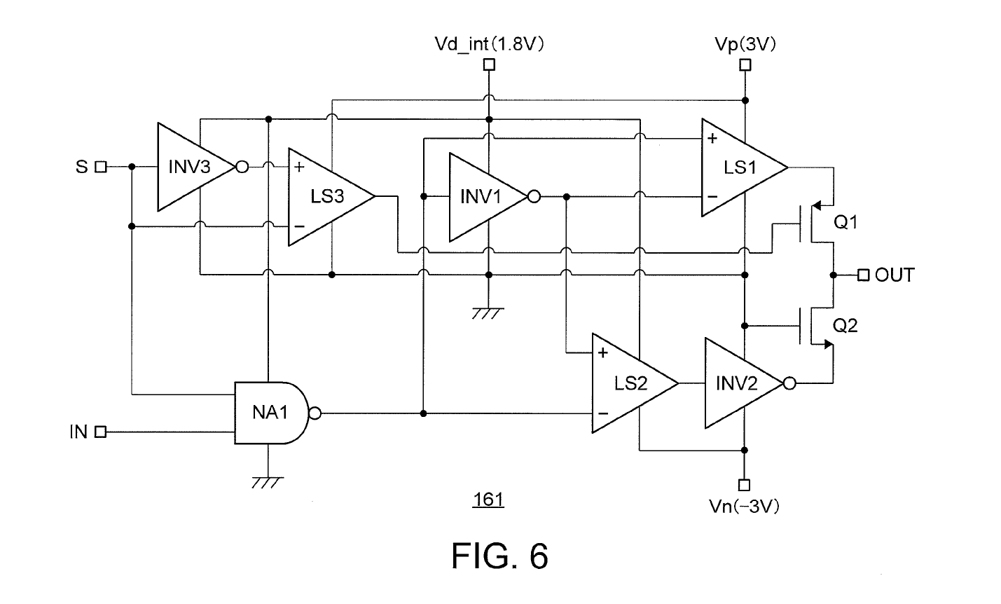

FIG. 6 is a circuit diagram illustrating the tri-state level shifter 161. The tri-state level shifter 161 includes inverters INV1 to INV3, level shifters LS1 to LS3, an NAND circuit NA1, a PMOS transistor Q1, and an NMOS transistor Q2.

The inverters INV1, INV3 are CMOS inverters with the second positive potential Vd_int as a high potential power supply, and the reference potential as a low potential power supply.

The inverter INV2 is a CMOS inverter with the reference potential being a high potential power supply, and the negative potential Vn(−3 V) being a low potential power supply.

The level shifters LS1, LS3 convert the high level of the output signal to the level of the first positive potential Vp (3 V). The low level of the level shifters LS1, LS3 is the reference potential.

The level shifter LS2 converts the low level of the output signal to the negative potential Vn (−3 V). The high level of the output signal of the level shifter LS2 is the reference potential.

When the selector terminal S is at the high level, the tri-state level shifter 161 functions as an inverting level shifter. That is, the level of the signal having the high level of 1.8 V and the low level of 0 V at the input terminal IN is converted to the signal having the high level of 3 V and the low level of −3 V. At the same time, the signal is logically inverted and output from the output terminal OUT.

Meanwhile, when the selector terminal S is at the low level, both the PMOS transistor Q1 and the NMOS transistor Q2 enter an off-state, and the output terminal OUT comes to have a high impedance.

According to the present embodiment, as described above, the control data C1, C2, and so on for controlling the second semiconductor switch 20 are converted into the multi-value parallel signals PS1, PS2, and so on, and such multi-value parallel signals PS1, PS2, and so on are supplied to the second semiconductor switch 20. Therefore, the number of input and output terminals of the first and second semiconductor switches 10, 20 can be decreased. Accordingly, the size of the first and second semiconductor switches 10, 20 can be made smaller.

In addition, since the first positive potential Vp and the negative potential Vn, which are used to operate the first and second switching circuits 15, 25, are used to provide multi-value signals and binary signals, it is not necessary to add the power supply circuit to the first and second semiconductor switches 10, 20 to provide the multi-value signals and the binary signals.

The first semiconductor switch 10 may control another semiconductor switch other than the second semiconductor switch 20 using the multi-value parallel signals PS1, PS2, and so on. Another semiconductor switch may be provided, for example, in a high frequency signal path other than that of the first and second semiconductor switches 10, 20.

Further, the second semiconductor switch 20 may not be controlled by the first semiconductor switch 10. Alternatively, the second semiconductor switch 20 may be controlled by multi-value parallel signals PS1, PS2, and so on that have been generated by another circuit, such as a power amplifier, to which the clock signal CK and the serial data Data are supplied.

The second semiconductor switch 20 may include the serial interface circuit 12 and the multi-value conversion circuit 16, instead of the binary conversion circuit 22. The first semiconductor switch 10 may include the binary conversion circuit 22 instead of the serial interface circuit 12 and the multi-value conversion circuit 16. That is, the clock signal CK and serial data Data may be supplied to the second semiconductor switch 20, such that the second semiconductor switch 20 generates the multi-value parallel signals PS1, PS2, and so on, and supplies them to the first semiconductor switch 10.

The first semiconductor switch 10 may supply the first positive potential Vp and the negative potential Vn to the second semiconductor switch 20. In this case, the power supply circuit 21 of the second semiconductor switch 20 should only generate the second positive potential Vd_int, such that the size of the second semiconductor switch 20 can be decreased.

Meanwhile, the multi-value conversion circuit 16 should only convert the control data C1, C2, and so on, into the multi-value parallel signals PS1, PS2, and so on, which have at least four values including the first positive potential Vp, the second positive potential Vd_int, the negative potential Vn, and the reference potential. Alternatively, the control data C1, C2, and so on may be converted into multi-value parallel signals PS1, PS2, and so on that include at least five values.

### Second Embodiment

A second embodiment differs from the first embodiment in that a first semiconductor switch 10A controls a second semiconductor switch 20A with serial data Data2. The description below will focus on what differs from the first embodiment.

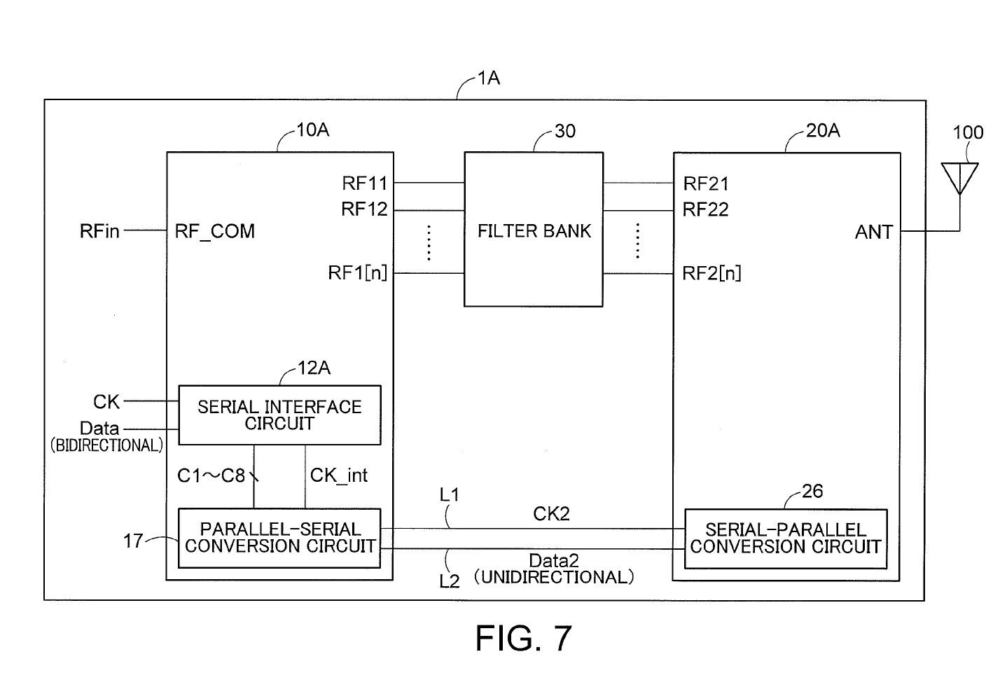

FIG. 7 is a block diagram of a high frequency module 1A according to the second embodiment. In the high frequency module 1A, the internal structures of the first semiconductor switch 10A and the second semiconductor switch 20A are different from those of the first embodiment.

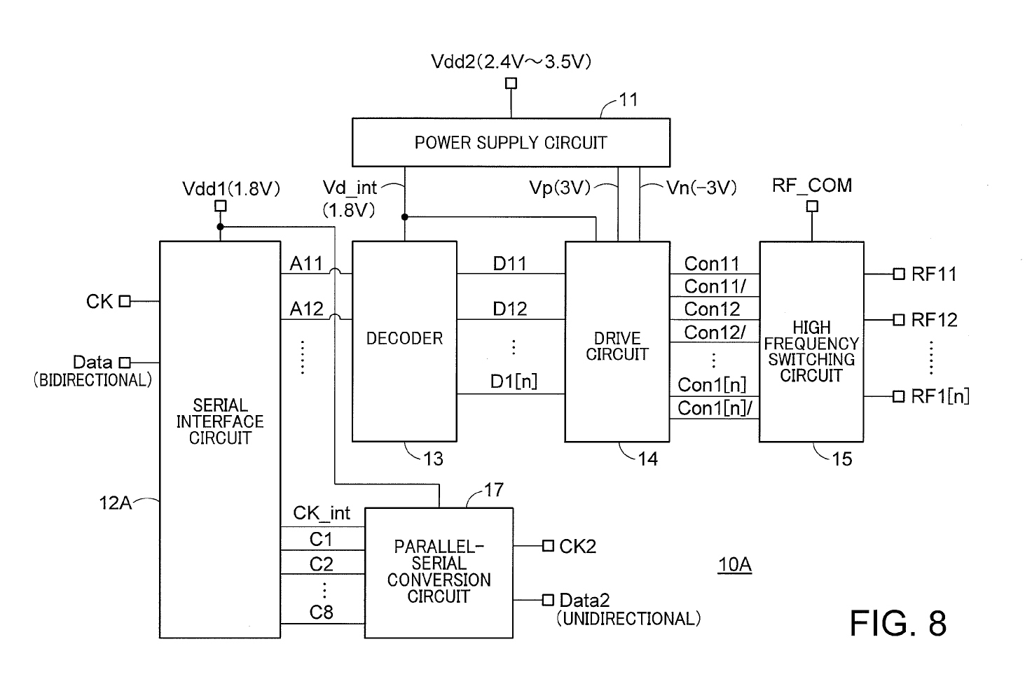

FIG. 8 is a block diagram of the first semiconductor switch 10A of FIG. 7. The first semiconductor switch 10A differs from the first semiconductor switch of FIG. 2 in that a serial interface circuit 12A has a different function and that a parallel-serial conversion circuit 17 is provided instead of the multi-value conversion circuit 16.

The serial interface circuit 12A converts the first serial data Data into first parallel data in synchronism with the clock signal CK, and stores the first parallel data in an internal register. The serial interface circuit 12A supplies, among the first parallel data stored therein, control data A11, A12, and so on for controlling the first switching circuit 15 to the decoder 13. The serial interface circuit 12A also supplies control data C1 to C8 for controlling the second semiconductor switch 20A to the parallel-serial conversion circuit 17. An example of 8-bit control data C1 to C8 is described herein. The serial interface circuit 12A supplies an internal clock signal CK_int, which is in synchronism with the clock signal CK, to the parallel-serial conversion circuit 17.

The parallel-serial conversion circuit 17 converts the control data C1 to C8 into second serial data Data2 during a switching period to switch the second switching circuit 25, and supplies the second serial data Data2 to the second semiconductor switch 20A via a second signal line L2.

The parallel-serial conversion circuit 17 also supplies, during the switching period, a clock signal CK2 that is synchronized with the internal clock signal CK_int, that is, a clock signal CK2 that is synchronized with the second serial data Data2, to the second semiconductor switch 20A via a first signal line L1. The second serial data Data2 is output unidirectionally, which is different from the first serial data Data. A circuit scale of such a parallel-serial conversion circuit 17 is relatively small.

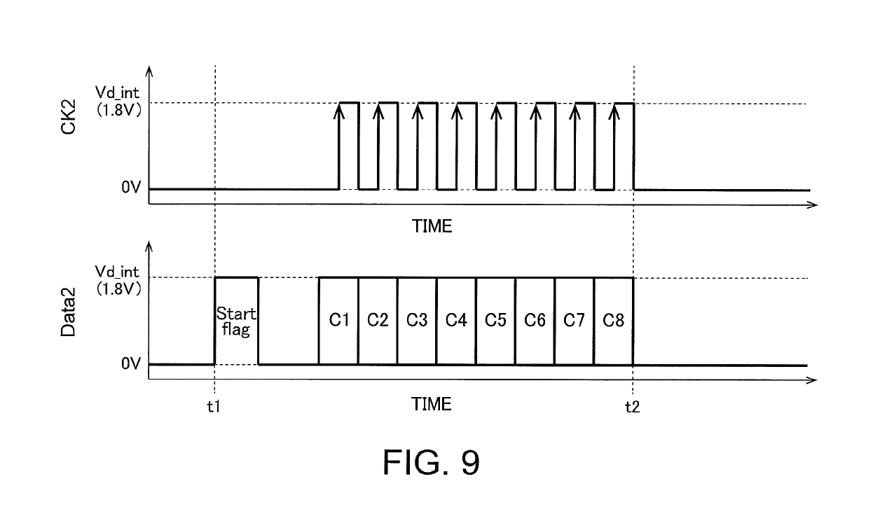

FIG. 9 is a waveform diagram of the clock signal CK2 and the second serial data Data2.

Both the clock signal CK2 and the second serial data Data2 are at a low level during a period other than the switching period (time t1 to t2).

At the start of the switching period (time t1), a start flag is generated in the second serial data Data2 while the clock signal CK2 is at the low level. The start flag is actually a pulse.

After the start flag is generated, a clock pulse is generated in the clock signal CK2, and the control data C1 to C8 are successively generated in the second serial data Data2 in synchronism with the clock signal CK2. When the last bit of the control data, i.e., the control data C8, is generated, the generation of the clock pulse of the clock signal CK2 is ended.

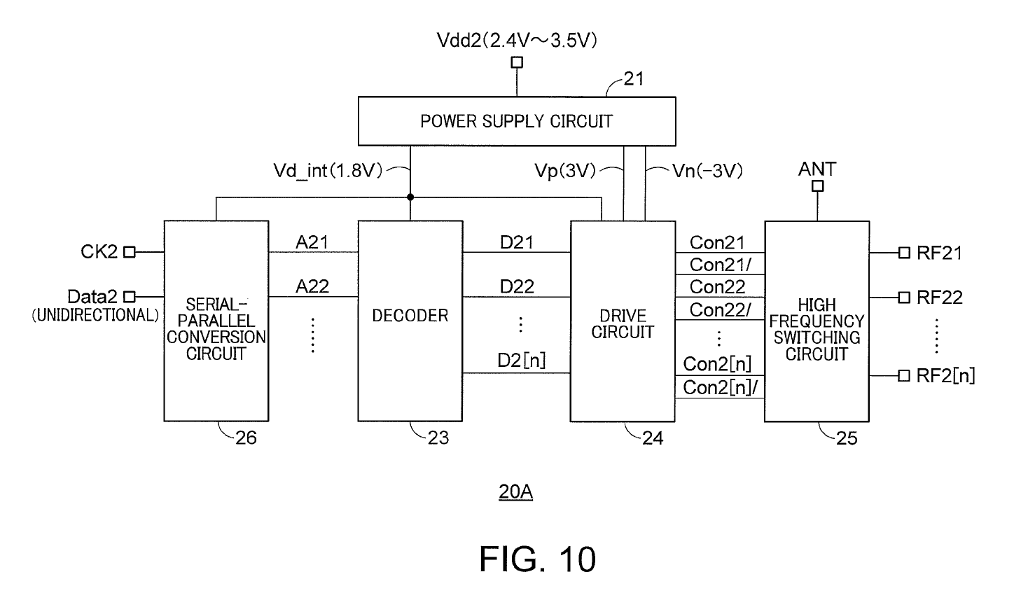

FIG. 10 is a block diagram of the second semiconductor switch 20A of FIG. 7. As illustrated in FIG. 10, the second semiconductor switch 20A differs from the second semiconductor switch of FIG. 6 in that a serial-parallel conversion circuit 26 is provided instead of the binary conversion circuit 22.

The serial-parallel conversion circuit 26 converts the second serial data Data2 into second parallel data A21, A22, and so on in synchronism with the clock signal CK2.

Similar to the first embodiment, the second switching circuit 25 switches the plurality of high frequency signal paths based on the second parallel data A21, A22, and so on.

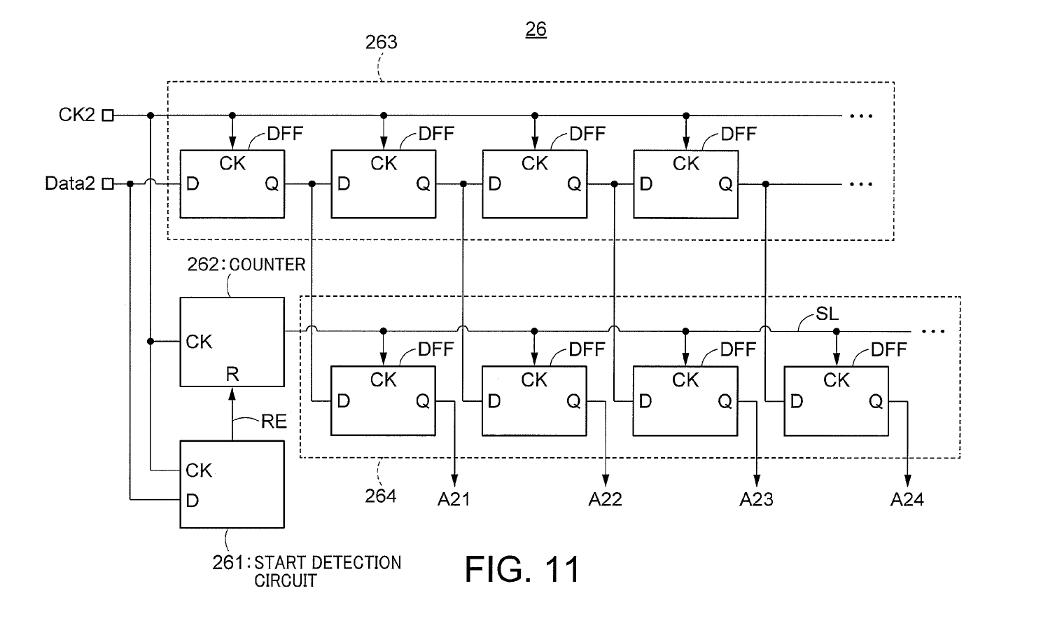

FIG. 11 is a block diagram illustrating the serial-parallel conversion circuit 26 of FIG. 10. The serial-parallel conversion circuit 26 includes a start detection circuit 261, a counter 262, a shift register 263, and a register for a switch control signal 264.

The start detection circuit 261 resets the counter 262 with a reset signal RE in response to detection of the start flag in the second serial data Data2 while the clock signal CK2 is at the low level.

The counter 262 is an 8-bit counter that counts clock pulses of the clock signal CK2. When 8 bits are counted, the counter outputs a latch signal SL in synchronism with a falling edge of the last clock pulse of the clock signal CK2.

The shift register 263 includes a plurality of D-type flip flops (DFF), which are connected in tandem, and successively shifts the second serial data Data2 in synchronism with the clock signal CK2.

The register for the switch control signal 264 includes a plurality of D-type flip flops (DFF), and latches the output data of the plurality of D-type flip flops of the shift register 263 according to the latch signal SL from the counter 262. The output data of the plurality of D-type flip flops of the register for the switch control signal 264 are the second parallel data A21, A22, and so on.

As illustrated in FIG. 9, the clock signal CK2 and the second serial data Data2 are generated in such a manner that the shift register 263 latches the second serial data Data2 in synchronism with a rising edge of the clock signal CK2.

A circuit scale of such a serial-parallel conversion circuit 26 is also relatively small.

According to the present embodiment, as described above, the control data C1 to C8 for controlling the second semiconductor switch 20A are converted into the second serial data Data2 and supplied to the second semiconductor switch 20A. Therefore, two signal lines to transmit the second serial data Data2 and the clock signal CK2 should be provided. When 3-bit or larger than 3-bit control data need to be supplied, it is possible to decrease, compared to the comparative example described above, the number of the input terminals, the output terminals, the input pads, the output pads, as well as the number of the ESD protection elements that are connected to the above components. Accordingly, the chip size of the first and second semiconductor switches 10A, 20A can be decreased and made smaller than those of the comparative example.

The first semiconductor switch 10A may supply the first positive potential Vp and the negative potential Vn to the second semiconductor switch 20A using another two power lines other than the first and second signal lines L1, L2. In that case, the size of the second semiconductor switch 20A can further be decreased, because only the second positive potential Vd_int should be generated by the power supply circuit 21 of the second semiconductor switch 20A.

### Third Embodiment

A third embodiment differs from the second embodiment in that power is supplied from the first semiconductor switch 10B to the second semiconductor switch 20B via the first and second signal lines L1, L2. The description below will focus on what differs from the second embodiment.

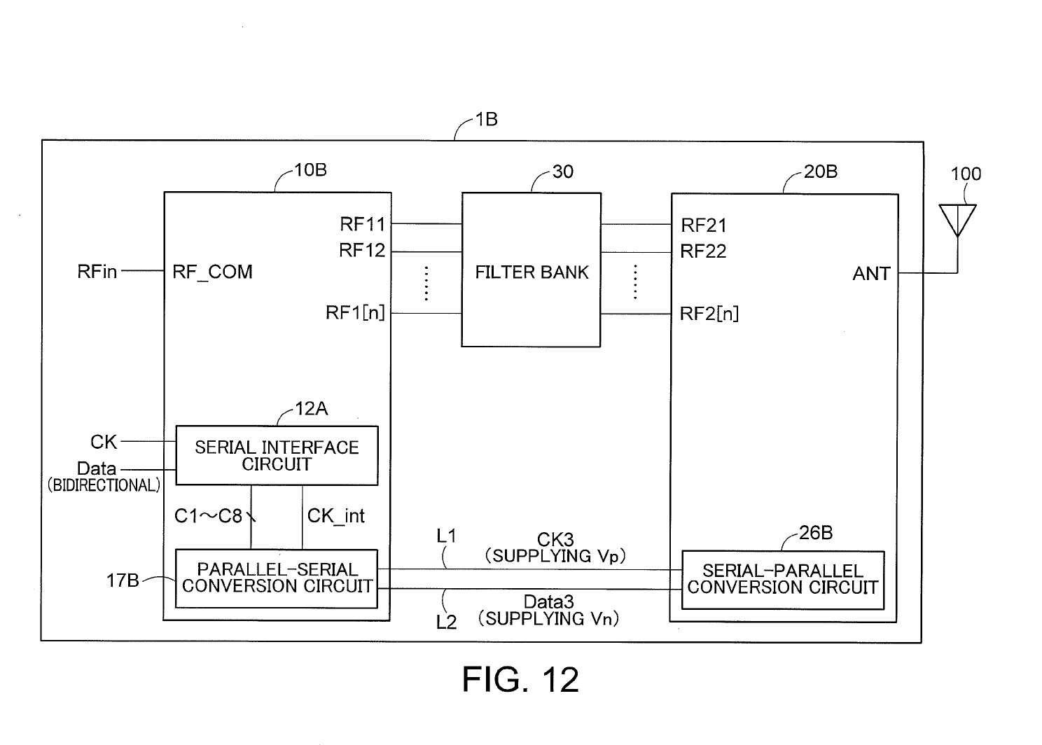

FIG. 12 is a block diagram of a high frequency module 1B according to the third embodiment. In the high frequency module 1B, the internal structures of the first semiconductor switch 10B and the second semiconductor switch 20B are different from those of the second embodiment.

In the first semiconductor switch 10B, the function of a parallel-serial conversion circuit 17B differs from the first semiconductor switch of the second embodiment.

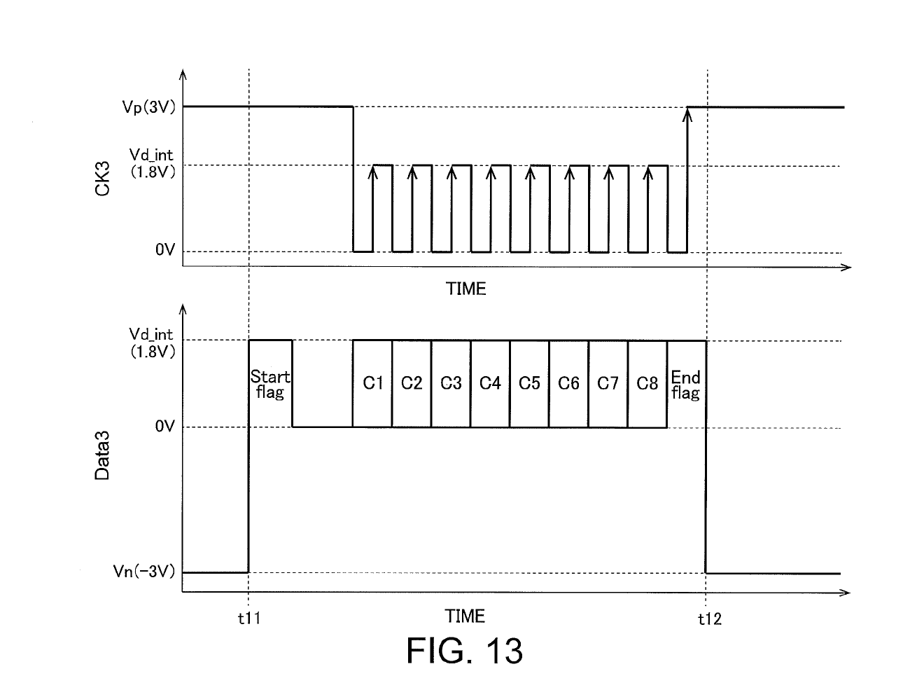

FIG. 13 is a waveform diagram of a clock signal CK3 and second serial data Data3. As illustrated in FIG. 13, the clock signal CK3 is at the first positive potential (first potential) Vp and the second serial data Data3 is at the negative potential (second potential) Vn during a period other than the switching period (time t11 to t12) to switch the second switching circuit 25.

Specifically, the parallel-serial conversion circuit 17B supplies the first positive potential Vp to the first signal line L1 and the negative potential Vn to the second signal line L2 during the period other than the switching period (time t11 to t12).

In the parallel-serial conversion circuit 17B, a start flag is generated in the second serial data Data3 at the start of the switching period (time t11), when the clock signal CK3 is at the first positive potential Vp. The start flag is actually a pulse having the second positive potential Vdd_int.

After the start flag is generated, a clock pulse is generated in the clock signal CK3, and the control data C1 to C8 are successively generated in the second serial data Data3 in synchronism with the clock signal CK3. After the last bit data C8 is generated, an end flag, which marks the completion of transmission of the switching signal, is generated, and the generation of the clock signal is ended. The end flag is at the high level. During the switching period, in the clock signal CK3 and the second serial data Data3, the low level of is 0 V, and the high level is the second positive potential Vd_int.

After the end flag is generated, at time t12, the clock signal CK3 returns to the first positive potential Vp and the second serial data Data3 returns to the negative potential Vn.

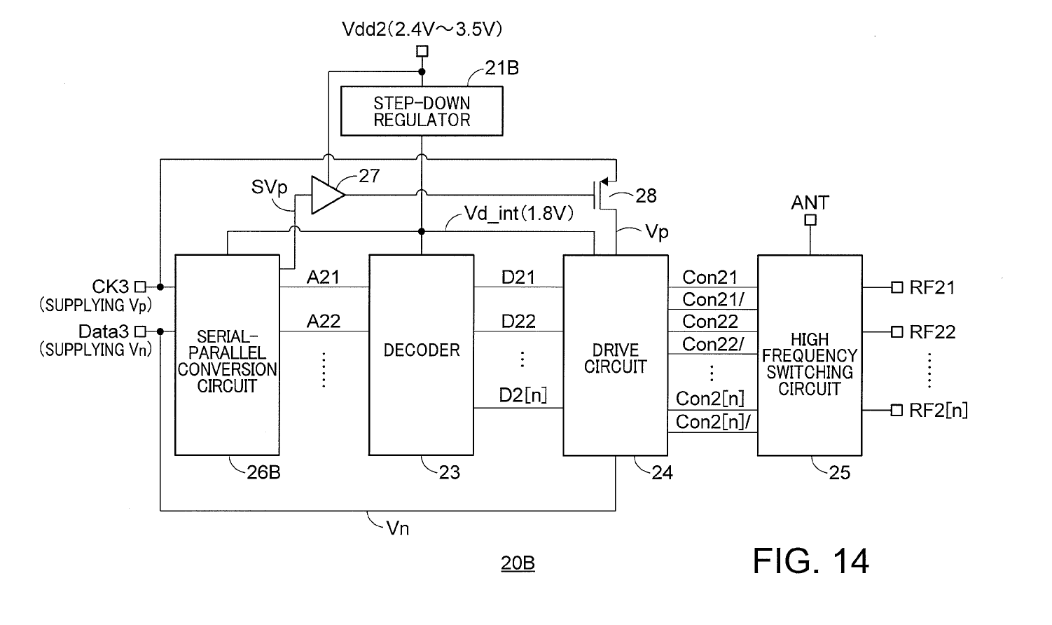

FIG. 14 is a block diagram of the second semiconductor switch 20B of FIG. 12. As illustrated in FIG. 14, the second semiconductor switch 20B differs from the second semiconductor switch of FIG. 10 in that a step-down regulator 21B is provided instead of the power supply circuit 21, and a buffer 27 and a PMOS transistor (switching element) 28 are also provided. The function of the serial-parallel conversion circuit 26B also differs from the serial-parallel conversion circuit of FIG. 10.

The serial-parallel conversion circuit 26B outputs a low-level or high-level Vp interrupt signal SVp, in addition to the function provided in the second embodiment.

The buffer 27 operates using an external power supply potential Vdd2 as a power supply, and converts the high signal level of the Vp interrupt signal SVp into the external power supply potential Vdd2 which is then supplied to the gate of the PMOS transistor 28. The low level of the Vp interrupt signal SVp is the reference potential. The external power supply potential Vdd2 is supplied to the gate of the PMOS transistor 28 during the switching period, and the reference potential is supplied during a period other than the switching period.

The PMOS transistor 28 has its source connected to the first signal line L1, and its drain connected to the drive circuit 24. The PMOS transistor 28 interrupts a current path between the first signal line L1 and the drive circuit 24 during the switching period, and conducts the current path between the first signal line L1 and the drive circuit 24 in a period other than the switching period.

The second signal line L2 is connected to the drive circuit 24.

The drive circuit 24 receives the first positive potential Vp and the negative potential Vn via the first and second signal lines L1, L2, respectively, and generates the control signals Con21 to Con2[n], Con21/ to Con2[n]/, each having two values including the first positive potential Vp and the negative potential Vn based on the second parallel data A21, A22, and so on.

Therefore, the second semiconductor switch 20B does not include the power supply circuit that generates the first positive potential Vp and the negative potential Vn. The step-down regulator 21B steps down the external power supply potential Vdd2 to generate the second positive potential Vd_int.

Assuming that the minimum value of the external power supply potential Vdd2 is Vdd2_min, the threshold value of the PMOS transistor 28 is set to |Vth|>Vp−Vdd2_min. For example, if Vp=3 V and Vdd2_min=2.4 V, it is set to |Vth|>0.6 V.

When the threshold value Vth is set in this manner, the PMOS transistor 28 enters the off-state when the Vp interrupt signal SVp is at the high level, such that the first positive potential Vp is not supplied to the drive circuit 24, even when the external power supply potential Vdd2 is at the minimum value Vdd2_min. As a result, an unnecessary operation of the drive circuit 24 can be suppressed during the switching period.

Meanwhile, when the Vp interrupt signal SVp is at the low level, the PMOS transistor 28 enters the on-state, and the first positive potential Vp is supplied to the drive circuit 24.

Next, the operation of the serial-parallel conversion circuit 26B will be described by referring to FIG. 13. For example, the basic structure of the serial-parallel conversion circuit 26B is similar to the serial-parallel conversion circuit of FIG. 11, and a circuit to generate a Vp interrupt signal SVp and a register for storing an end flag, in which the end flag is stored, may additionally be provided (not illustrated).

(1) Operation when the clock signal CK3 is at the first positive potential Vp and the second serial data Data3 is at the negative potential Vn (until time t11):

The second parallel data A21, A22, and so on are latched data that have been latched during the switching operation. Also, the Vp interrupt signal SVp is at 0 V.

At this time, both the first positive potential Vp and the negative potential Vn are supplied to the drive circuit 24, while the decode signals D21, D22, and so on that have been determined in the previous switching operation are input. The drive circuit 24 generates the control signals Con21 to Con2[n], and Con21/ to Con2[n]/. The second switching circuit 25 selects the high frequency signal path based on the control signals Con21 to Con2[n], and Con21/ to Con2[n]/.

(2) Operation when the clock signal CK3 is at the first positive potential Vp and the start flag is detected from the second serial data Data3 (at time t11):

The Vp interrupt signal SVp comes to be at the high level and the supply of the first positive potential Vp to the drive circuit 24 is interrupted.

Also, the counter and the register for storing the end flag in the serial-parallel conversion circuit 26B are reset.

(3) Operation when the clock pulse is generated in the clock signal CK3, and the control data C1 to C8 are input as the second serial data Data3:

The control data C1 to C8 are successively stored in the shift register in the serial-parallel conversion circuit 26B.

(4) Operation when the end flag is recognized:

The control data C1 to C8 for each bit of the shift register in the serial-parallel conversion circuit 26B are latched in the register for storing the control signals, while the Vp interrupt signal SVp becomes 0 V. As a result, the PMOS transistor 28 enters the on-state, and the first positive potential Vp is supplied to the drive circuit 24. The high frequency signal path of the second switching circuit 25 is then switched based on the new control signals Con21 to Con2[n] and Con21/ to Con2[n]/.

According to the present embodiment, as described above, the first positive potential Vp and the negative potential Vn are supplied from the first semiconductor switch 10B to the second semiconductor switch 20B. Therefore, it is not necessary to generate the first positive potential Vp and the negative potential Vn in the second semiconductor switch 20B. The second semiconductor switch 20B can be made smaller than the second semiconductor switch of the second embodiment.

The first positive potential Vp and the negative potential Vn are supplied using the first and second signal lines L1, L2. Accordingly, it is possible to decrease the number of the input and output terminals and the size of the first and second semiconductor switches 10B, 20B, when compared with the second embodiment in which the first positive potential Vp and the negative potential Vn are supplied using the two power supply lines other than the first and second signal lines L1, L2.

### Fourth Embodiment

A fourth embodiment differs from the second embodiment in that a first semiconductor switch 10C controls a second semiconductor switch 20C with multi-value serial data. The description below will focus on what differs from the second embodiment.

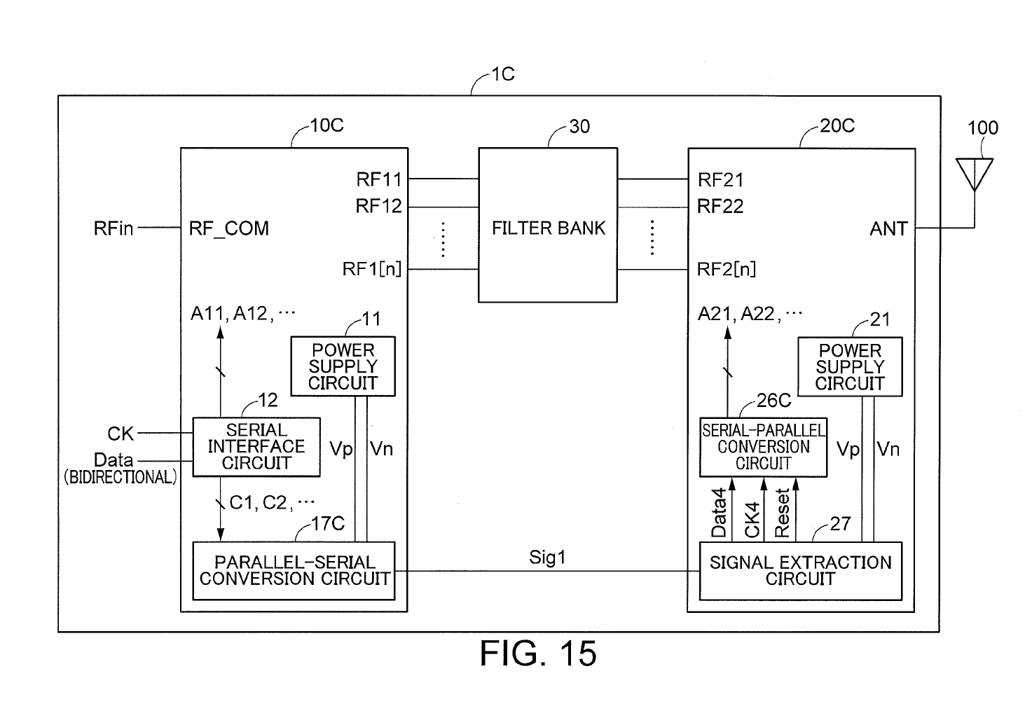

FIG. 15 is a block diagram of a high frequency module 1C according to the fourth embodiment. In the high frequency module 1C, the internal structures of the first semiconductor switch 10C and the second semiconductor switch 20C are different from those of the second embodiment.

In the first semiconductor switch 10C, the function of a parallel-serial conversion circuit 17C is different from that of the second embodiment. The parallel-serial conversion circuit 17C converts the control data C1, C2, and so on, which are included in the first parallel data and control the second semiconductor switch 20C, into second serial data Sig1, and transmits the second serial data Sig1 to the second semiconductor switch 20C. That is, the parallel-serial conversion circuit 17C functions as a four-value serial data transmission circuit.

The second serial data Sig1 has four values including the first positive potential Vp, the second positive potential Vd_int, the negative potential Vn, and the reference potential. The second serial data Sig1 includes a reset signal Reset, a clock signal CK4, and third serial data Data4 that is synchronized with the clock signal CK4.

The second semiconductor switch 20C includes, in addition to the structure of the second embodiment, a signal extraction circuit (four-value serial data receiving circuit) 27. The function of the serial-parallel conversion circuit 26C also differs from that of the second embodiment.

The signal extraction circuit 27 extracts, from the second serial data Sig1, the reset signal Reset, the clock signal CK4, and third serial data Data4 based on the first positive potential Vp, the second positive potential Vd_int, the negative potential Vn, and the reference potential. The reset signal Reset, the clock signal CK4, and the third serial data Data4 have two values including the second positive potential Vdd_int and the reference potential.

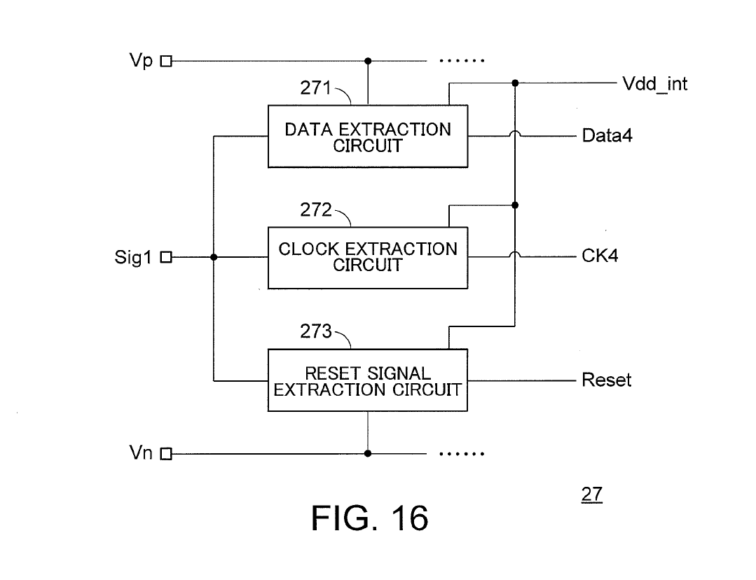

FIG. 16 is a block diagram of the signal extraction circuit 27. As illustrated in FIG. 16, the signal extraction circuit 27 includes a data extraction circuit 271, a clock extraction circuit 272, and a reset signal extraction circuit 273.

The data extraction circuit 271 receives the first positive potential Vp and the second positive potential Vdd_int as the power supply potential. The data extraction circuit 271 extracts the third serial data Data4 from the second serial data Sig1.

The clock extraction circuit 272 receives the second positive potential Vdd_int as the power supply potential. The clock extraction circuit 272 extracts the clock signal CK4 from the second serial data Sig1.

The reset signal extraction circuit 273 receives the negative potential Vn and the second positive potential Vdd_int as the power supply potential. The reset signal extraction circuit 273 extracts the reset signal Reset from the second serial data Sig1.

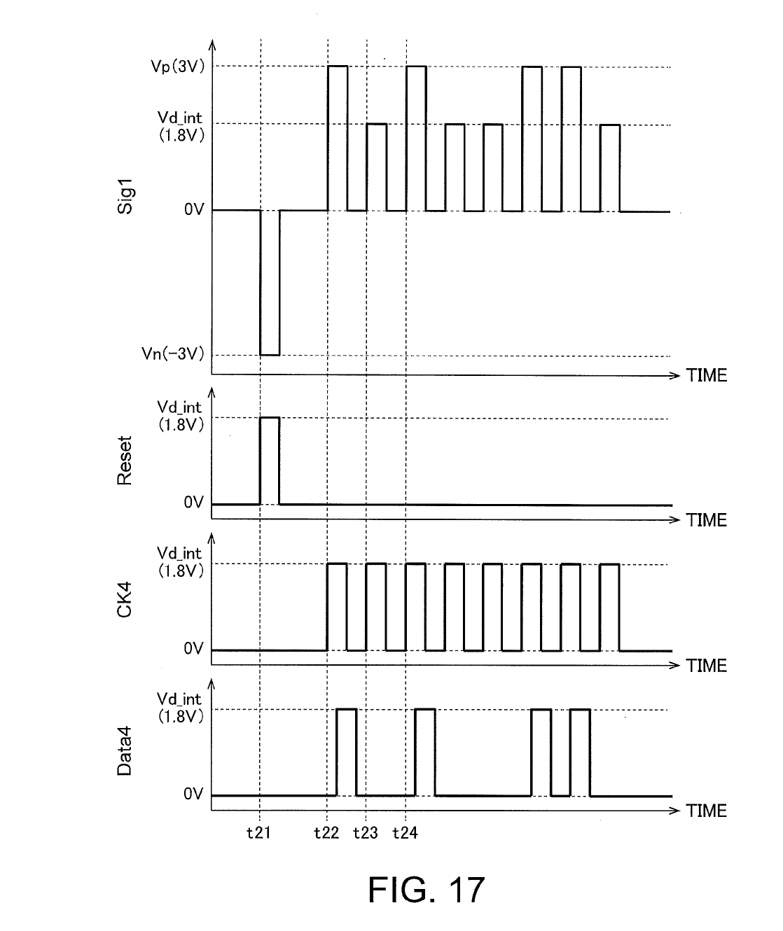

FIG. 17 is a waveform diagram illustrating the second serial data Sig1, the reset signal Reset, the clock signal CK4, and the third serial data Data4.

The second serial data Sig1 is a return-to-zero (RTZ) signal including a pulse of the first positive potential Vp, a pulse of the second positive potential Vd_int, and a pulse of the negative potential Vn.

First, at time t21, a pulse of the negative potential appears in the second serial data Sig1.

The extracted reset signal Reset includes a reset pulse corresponding to the pulse of the negative potential of the second serial data Sig1. That is, the reset signal Reset comes to be at the high level during a period corresponding to the pulse of the negative potential from time t21.

Next, in the second serial data Sig1, a pulse of the first positive potential Vp appears at time t22, and a pulse of the second positive potential Vd_int appears at time t23. Similarly, after the time t24, the pulse of the first positive potential Vp or the pulse of the second positive potential Vd_int appears periodically in the second serial data Sig1.

The extracted clock signal CK4 has clock pulses corresponding to the pulse of the first positive potential Vp and the pulse of the second positive potential Vd_int. Therefore, the clock signal CK4 comes to be at the high level during the period after time t22 corresponding to the pulse of the first positive potential Vp, comes to be at the high level during the period after time t23 corresponding to the pulse of the second positive potential Vd_int, and so on also after time t24.

The extracted third serial data Data4 includes a pulse corresponding to the pulse of the first positive potential Vp, that is delayed from the pulse of the first positive potential Vp.

The third serial data Data4 comes to be at the high level during the period after time t22 corresponding to the pulse of the first positive potential Vp, and returns to the low level after that. The third serial data Data4 then comes to be at the high level during the period after time t24 corresponding to the pulse of the first positive potential Vp, and the process continues in the same manner after that. That is, the third serial data Data4 is at the low level in the period corresponding to the pulse of the second positive potential Vd_int.

Returning to FIG. 15, the reset signal Reset, the third serial data Data4, and the clock signal CK4 from the signal extraction circuit 27 are input to the serial-parallel conversion circuit 26C. The serial-parallel conversion circuit 26C is reset by the reset signal Reset, and then converts the third serial data Data4 into the second parallel data A21, A22, and so on in synchronism with the clock signal CK4.

Since the pulse of the third serial data Data4 is delayed, as described above, the serial-parallel conversion circuit 26C can latch the third serial data Data4 at the falling edge of the clock signal CK4.

Similar to the second embodiment, the second switching circuit 25 switches the plurality of high frequency signal paths based on the second parallel data A21, A22, and so on.

As described above, in the present embodiment, only one signal line is provided between the first semiconductor switch 10C and the second semiconductor switch 20C, regardless of the bit numbers of the control data C1, C2, and so on.

In contrast, in the comparative example, three signal lines are provided when the control data is 3-bit data, and the number of the signal lines is increased according to the increase of the bit number of the control data.

Therefore, according to the present embodiment, as the bit number of the control data C1, C2, and so on for controlling the second semiconductor switch 20 is increased, the size of the high frequency module 1C can further be decreased compared to the comparative example.

The size of the high frequency module 1C can also be made smaller than the second embodiment that requires two signal lines including the first and second signal lines L1, L2.

### Fifth Embodiment

A fifth embodiment differs from the fourth embodiment in that the power is supplied from a first semiconductor switch 10D to a second semiconductor switch 20D. The description below will focus on what differs from the fourth embodiment.

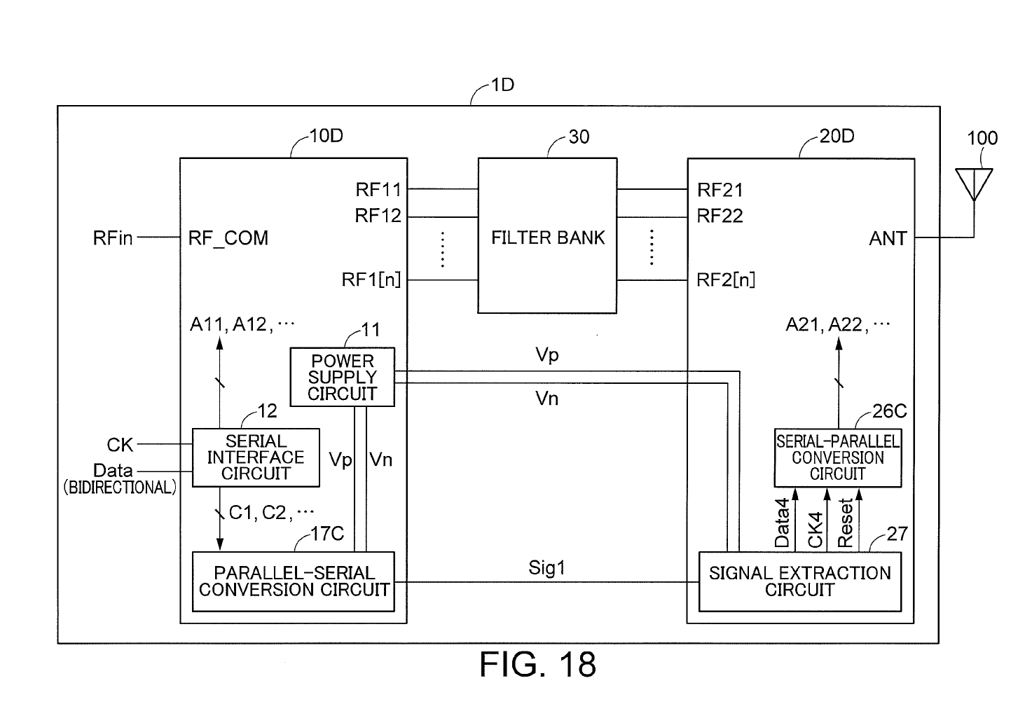

FIG. 18 is a block diagram of a high frequency module 1D according to the fifth embodiment. In the high frequency module 1D, the internal structures of the first semiconductor switch 10D and the second semiconductor switch 20D are different from those of the fourth embodiment. Specifically, the power supply circuit 11 of the first semiconductor switch 10D generates the first positive potential Vp and the negative potential Vn, and supplies the first positive potential Vp and the negative potential Vn to the second semiconductor switch 20D through two power supply lines.

According to the present embodiment, the second semiconductor switch 20D does not need to generate the first positive potential Vp and the negative potential Vn. Therefore, the structure of the second semiconductor switch 20D can be simplified.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor switch comprising:
a serial interface circuit configured to convert serial data into parallel data;
a drive circuit configured to generate a control signal comprising two values including a first positive potential and a negative potential, based on the parallel data;
a switching circuit configured to switch a plurality of signal paths based on the control signal; and
a multi-value conversion circuit configured to convert control data included in the parallel data into a multi-value parallel signal, the multi-value parallel signal comprising at least four values including the first positive potential and the negative potential.

2. The semiconductor switch according to claim 1, wherein
the serial data and the parallel data comprise two values including a second positive potential and a reference potential, and
the multi-value conversion circuit converts the control data into the multi-value parallel signal comprising at least four values including the first positive potential, the second positive potential, the negative potential, and the reference potential.

3. A semiconductor switch comprising:
a binary conversion circuit configured to convert a multi-value parallel signal into binary parallel data, the multi-value parallel signal comprising at least four values including a first positive potential and a negative potential;
a drive circuit configured to generate a control signal comprising two values including the first positive potential and the negative potential, based on the parallel data; and
a switching circuit configured to switch a plurality of signal paths based on the control signal.

4. The semiconductor switch according to claim 3, wherein
the binary conversion circuit converts the multi-value parallel signal comprising at least four values including the first positive potential, a second positive potential, the negative potential, and a reference potential, into the parallel data comprising two values including the second positive potential and the reference potential.

5. A switching system comprising:
a first semiconductor switch; and
a second semiconductor switch,
wherein the first semiconductor switch comprises
a serial interface circuit configured to convert first serial data into first parallel data,
a first switching circuit configured to switch a plurality of signal paths based on the first parallel data, and
a parallel-serial conversion circuit configured to convert control data into second serial data, and supply the second serial data to the second semiconductor switch, the control data being included in the first parallel data and controlling the second semiconductor switch, and
wherein the second semiconductor switch comprises a second switching circuit configured to switch a plurality of signal paths based on the second serial data.

6. The switching system according to claim 5, wherein
the parallel-serial conversion circuit supplies a clock signal to the second semiconductor switch via a first signal line and the second serial data to the second semiconductor switch via a second signal line, during a switching period to switch the second switching circuit, the clock signal being synchronized with the second serial data,
the parallel-serial conversion circuit supplies a first potential to the first signal line and a second potential to the second signal line during a period other than the switching period,
the second semiconductor switch comprises
a serial-parallel conversion circuit configured to convert the second serial data into second parallel data in synchronism with the clock signal, and
a drive circuit configured to generate a control signal comprising two values including the first potential and the second potential based on the second parallel data, the first potential and the second potential being supplied to the drive circuit via the first signal line and the second signal line, and
the second switching circuit switches a plurality of signal paths based on the control signal.

7. The switching system according to claim 6, wherein
the second semiconductor switch comprises a switching element configured to interrupt a current path between the first signal line and the drive circuit during the switching period, and conduct the electric path between the first signal line and the drive circuit during a period other than the switching period.

8. The switching system according to claim 7, wherein
the first potential is a first positive potential,
the switching system further comprising a regulator configured to generate a second positive potential by stepping down an external power supply potential,
wherein the second serial data and the clock signal comprise two values including the second positive potential and a reference potential during the switching period,
the switching element is a PMOS transistor comprising a gate, a source connected to the first signal line, and a drain connected to the drive circuit, the external power supply potential is supplied to the gate during the switching period and the reference potential is supplied to the gate during the period other than the switching period, and
a threshold value Vth of the PMOS transistor is set to |Vth|>Vp−Vdd2_min, where Vp represents the first positive potential and Vdd2_min represents the minimum value of the external power supply potential.

9. The switching system according to claim 6, wherein
the first potential is a first positive potential and the second potential is a negative potential.

10. The switching system according to claim 9, wherein
the second serial data and the clock signal comprise two values including a second positive potential and a reference potential during the switching period.

11. The switching system according to claim 5, wherein
the first semiconductor switch comprises a first drive circuit configured to generate a first control signal based on the first parallel data, the first control signal comprising two values including a first positive potential and a negative potential,
the first switching circuit switches a plurality of signal paths based on the first control signal,
the first serial data and the first parallel data comprise two values including a second positive potential and a reference potential, and
the parallel-serial conversion circuit converts the control data into the second serial data comprising at least four values including the first positive potential, the second positive potential, the negative potential, and the reference potential.

12. The switching system according to claim 11, wherein
the second serial data comprises a reset signal, a clock signal, and third serial data being synchronized with the clock signal,
the second semiconductor switch comprises
a signal extraction circuit configured to extract the reset signal, the clock signal, and the third serial data from the second serial data based on the first positive potential, the second positive potential, the negative potential, and the reference potential, and
a serial-parallel conversion circuit configured to convert, after being reset by the reset signal, the third serial data into second parallel data in synchronism with the clock signal, and
a second drive circuit configured to generate a second control signal comprising two values including the first positive potential and the negative potential, and
the second switching circuit switches the plurality of signal paths based on the second control signal.

13. The switching system according to claim 12, wherein
the second serial data is a return-to-zero (RTZ) signal comprising a pulse of the first positive potential, a pulse of the second positive potential, and a pulse of the negative potential,
the reset signal comprises a reset pulse corresponding to the pulse of the negative potential,
the clock signal comprises a clock pulse corresponding to the pulse of the first positive potential and the pulse of the second positive potential, and
the third serial data comprises a pulse corresponding to the pulse of the first positive potential or the pulse of the second positive potential.

14. The switching system according to claim 13, wherein
each of the reset signal, the clock signal, and the third serial data comprises two values including the second positive potential and the reference potential.

15. The switching system according to claim 14, wherein
the signal extraction circuit comprises
a data extraction circuit configured to extract the third serial data from the second serial data, the first positive potential and the second positive potential being supplied to the data extraction circuit as power supply potential,
a clock extraction circuit configured to extract the clock signal from the second serial data, the second positive potential being supplied to the clock extraction circuit as the power supply potential, and
a reset signal extraction circuit configured to extract the reset signal from the second serial data, the negative potential and the second positive potential being supplied to the reset signal extraction circuit as the power supply potential.

16. The switching system according to claim 13, wherein
the pulse of the third serial data is delayed from the pulse of the first positive potential or the pulse of the second positive potential.

17. The switching system according to claim 11, wherein
the first semiconductor switch comprises a power supply circuit configured to generate the first positive potential and the negative potential, and supply the first positive potential and the negative potential to the second semiconductor switch.

18. The switching system according to claim 11, wherein
the first positive potential is higher than the second positive potential.

19. The switching system according to claim 5, further comprising a filter bank comprising a plurality of filters, each filter having a different frequency characteristic, wherein
the first switching circuit selects a first signal node among a plurality of first signal nodes, and connects the selected first signal node to a first common node to switch the plurality of signal paths,
the second switching circuit selects a second signal node among a plurality of second signal nodes, and connects the selected second signal node to a second common node to switch the plurality of signal paths, and
each of the plurality of the first signal nodes is connected to a corresponding second signal node via a corresponding filter of the filter bank.
